(19) United States
(12) Patent Application Publication
(10) Pub. No.: US 2016/0278200 A1
(43) Pub. Date: Sep. 22, 2016

(54) Method of manufacturing a printed circuit and the corresponding printed circuit

(71) Applicant: THALES, COURBEVOIE (FR)

(72) Inventor: David Costes, Valence (FR)

(73) Assignee: THALES, COURBEVOIE (FR)

(21) Appl. No.: 15/074,503

(22) Filed: Mar. 18, 2016

(30) Foreign Application Priority Data
Mar. 20, 2015 (FR) 15 00551

(51) Int. Cl. H05K 1/02; H05K 3/46; H05K 3/40; H05K 1/18

(52) U.S. Cl. CPC H05K 1/0206; H05K 1/0298; H05K 1/185; H05K 3/46; H05K 3/4038; H05K 2201/08

(57) ABSTRACT

The manufacturing method gives the possibility of manufacturing a printed circuit comprising an electrically insulating substrate and electrically conductive elements borne by the substrate. The manufacturing method comprises the manufacturing of the insulating substrate and of the conductive elements together by additive manufacturing.

### CROSS-REFERENCE TO RELATED APPLICATION

The present application claims priority to French Patent Application Serial No. 1500551 filed Mar. 20, 2015, the contents of which are hereby incorporated by reference in its entirety.

### FIELD OF THE INVENTION

The present invention relates to the field of printed circuits, and in particular the manufacturing of printed circuits.

### BACKGROUND OF THE INVENTION

A printed circuit has a multilayer structure formed with an alternation of electrically insulating layers and of conductive layers, conductive tracks being formed in the conductive layers. Vias, that is metallized holes formed in at least one insulating layer, give the possibility of electrically connecting conductive tracks of two conductive layers separated by at least one insulating layer.

It is possible to manufacture a printed circuit having one or two conductive layers by providing a plate comprising an insulating supporting layer covered on one face or on each face with a conductive layer, for example in copper, and then etch tracks in each conductive layer, for example by chemical etching.

It is possible to manufacture printed circuits with at least three conductive layers by stacking the printed circuits having one or two conductive layers, with possible interposition of insulating plates, for example between two printed circuits with two conductive layers. A multilayer printed circuit comprises conductive layers (at least two in number) alternating with insulating layers.

In a same multilayer printed circuit, it is possible to provide thin conductive layers dedicated to transmission of low energy signals, and thick conductive layers dedicated to the transmission of high energy signals.

Because of the manufacturing of printed circuits with at least three conductive layers by stacking printed circuits having one or two conductive layers, each conductive layer has a uniform thickness, and the conductive tracks of each conductive layer have the same thickness. This results in that a conductive layer is generally dedicated to the transmission of high energy signals or to the transmission of low energy signals, and that high energy tracks and low energy tracks are not formed in a same conductive layer.

### SUMMARY OF THE INVENTION

One of the objects of the invention is to propose a method for manufacturing printed circuits giving the possibility of more freedom in the manufacturing of the printed circuit.

For this purpose, the invention proposes a method for manufacturing a printed circuit comprising an electrically insulating substrate and electrically conductive elements borne by the substrate, the method comprising the manufacturing of the insulating substrate and of conductive elements together by additive manufacturing.

According to particular embodiments, the manufacturing method comprises one or several of the following features, taken individually or according to all the technically possible combinations:
it comprises the manufacturing of at least one area in which a first conductive element and a second conductive element are sandwiched between two substrate portions, the first conductive element having a thickness, taken between two substrate portions, strictly smaller than that of the second conductive element;
it comprises the manufacturing of a first distinct area and a second distinct area, each comprising an alternated stack of substrate portions and of conductive elements, the first area and the second area having a number of conductive elements strictly less than the number of conductive elements of the second area;
it comprises the manufacturing of at least one area comprising at least one productive buried via (36) connecting two conductive elements separated by at least one substrate portion;
it comprises the manufacturing of at least one electronic component and/or at least one magnetic component in the thickness of the printed circuit;
it comprises the manufacturing of at least one thermal drain made in a hole extending through the printed circuit in the direction of the thickness, the thermal drain comprising at least one massive metal block with a section mating that of the hole;
the printed circuit is formed with a non-planar stable three-dimensional shape;
the printed circuit is manufactured by additive manufacturing together with a shell of an electronic device.

The invention also relates to a printed circuit obtained by the manufacturing method as defined above.

The invention notably relates to a printed circuit comprising an electrically insulating substrate and electrically conductive elements borne by the substrate, the printed circuit comprising at least one area in which a first conductive element and a second conductive element are sandwiched between two substrate portions, the first conductive element having a thickness, taken between the two substrate portions, strictly less than that of the second conductive element.

The invention also relates to a printed circuit comprising an electrically insulating substrate and electrically conductive elements formed on the substrate, the printed circuit comprising a first distinct area and a second distinct area, each comprising a stack of alternating substrate portions and conductive elements, the first area and the second area having a number of conductive elements strictly less than the number of conductive elements of the second area.

The invention also relates to a printed circuit comprising an electrically insulating substrate and electrically conductive elements borne on the insulated substrate, the printed circuit comprising at least one electronic component and/or at least one magnetic component formed in the thickness of the printed circuit.

The invention also relates to a printed circuit comprising an electrically insulating substrate and electrically conductive elements borne on the insulated substrate, the printed circuit comprising a thermal drain made in a hole crossing right through the printed circuit in the thickness direction, the thermal drain comprising at least one massive metal block with a section mating that of the hole.

The invention also relates to a printed circuit comprising an electrically insulating substrate and electrically conductive elements borne on the insulated substrate, the printed circuit being formed with a non-planar stable three-dimensional shape.

The invention further relates to a printed circuit comprising an electrically insulating substrate and electrically conductive elements borne by the insulating substrate, the printed circuit being manufactured by adding material together with an electronic device shell.

### BRIEF DESCRIPTION OF THE DRAWINGS

The invention and its advantages will be better understood upon studying the description which follows, only given as an example and made with reference to the appended drawings, wherein:

FIG. 1 illustrates the manufacturing of a printed circuit by addition of materials, in successive layers;

FIGS. 2 to 5 illustrate successive steps for manufacturing the printed circuit of FIG. 1;

FIG. 6 illustrates a system for manufacturing the printed circuit by addition of materials, using two manufacturing machines with addition of material;

FIGS. 7 to 9 illustrate printed circuits manufactured by addition of materials, having particular arrangements of the substrate and of the conductive layers;

FIG. 10 illustrates a printed circuit manufactured by addition of materials, comprising a thermal drain;

FIG. 11 illustrates a printed circuit comprising a thermal drain, obtained according to a standard manufacturing method, according to the state of the art;

FIG. 12 illustrates a printed circuit manufactured by adding materials, comprising a thermal drain with integrated electric insulation;

FIGS. 13 and 14 illustrate printed circuits manufactured by adding materials, respectively comprising electric components and a magnetic circuit integrated into the thickness of the printed circuit;

FIG. 15 illustrates a printed circuit manufactured by adding materials, having a three-dimensional shape; and

FIG. 16 illustrates a printed circuit manufactured by adding materials on a shell of a casing of an electronic piece of equipment.

### DETAILED DESCRIPTION

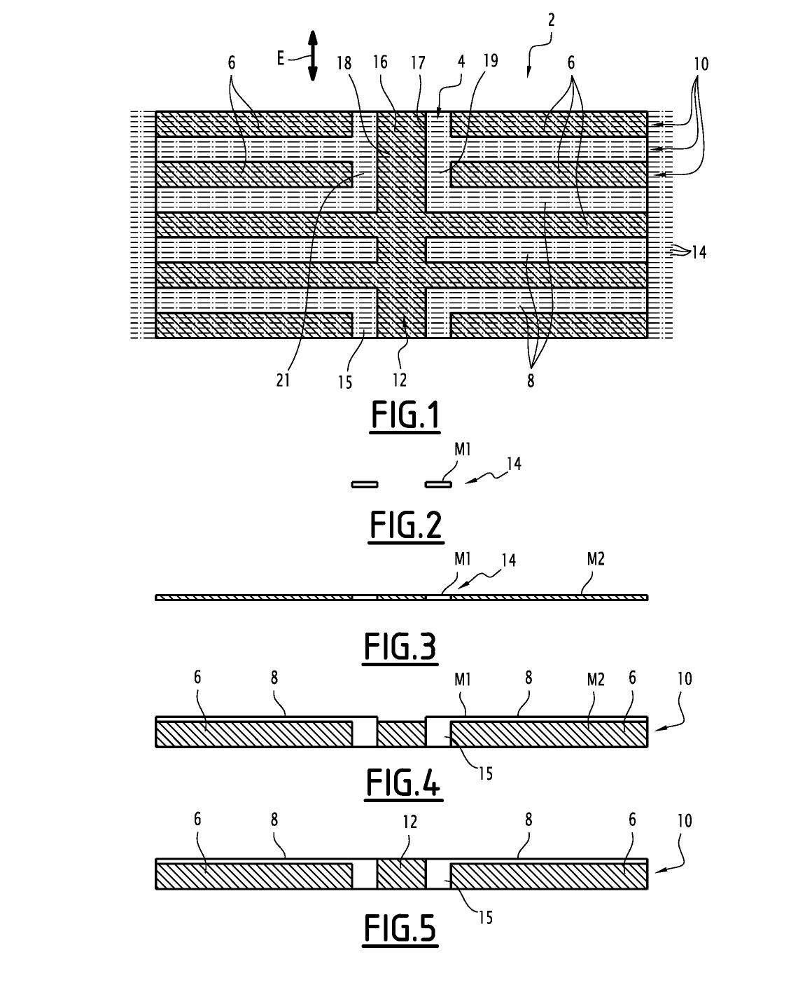

The printed circuit 2 of FIG. 1 comprises an electrically insulating substrate 4 and electrically conductive elements 6, 12 borne by the insulating substrate 4.

The printed circuit 2 here comprises a multilayer structure formed with a stack of structural layers 10 superposed along a stacking direction E.

In FIG. 1, certain structural layers 10 contain both insulating substrate portions 8 and conductive elements 6 or portions of conductive elements 6.

Certain areas of the printed circuit 2 (on the right and on the left in FIG. 1) comprise a stack of conductive elements 6 and of intercalary insulating substrate portions 8 alternated along the stacking direction E.

The printed circuit 2 comprises (at the center of FIG. 1) a conductive element forming a via 12 extending through the printed circuit 2 in the direction of the thickness and achieving an electric connection between at least two conductive elements 6 located in two distinct structural layers 10 and separated by an intercalary insulating substrate portion 8 interposed between both conductive elements 6.

As illustrated by parallel dotted lines, the printed circuit 2 is manufactured by additive manufacturing, by adding successive material layers. During this manufacturing, material layers are successively added, in order to form the printed circuit 2. The material layer between each pair of adjacent dotted lines (hereafter manufacturing layer 14) represents a layer of added materials during a manufacturing step by addition of materials.

The printed circuit 2 comprises two different materials, i.e. the insulating material of the substrate 4 and the conductive material of the conductive elements 6.

At least certain manufacturing layers 14 contain at least two different materials, here conductive material and insulating material.

FIGS. 2 to 5 illustrate steps for depositing manufacturing layers for the manufacturing by addition of material printed circuit 2.

FIGS. 2 and 3 illustrate the manufacturing of a structural layer 10 comprising two conductive elements 6 located on either side of a first segment of the via 12, by being separated and electrically insulated from the via 12 by a portion of the separation substrate 15, which here is ring shaped and surrounds the via 12.

The structural layer 10 is formed with several stacked manufacturing layers 14, and FIGS. 2 and 3 illustrate the manufacturing of the first manufacturing layer 14.

According to an embodiment, a material M1 followed by the other material M2 are added successively. In the illustrated example, the insulating material M1 (FIG. 2) is deposited first and then the conductive material M2 (FIG. 3). Alternatively, the order of addition of the materials is reversed. The operations of FIGS. 2 and 3 are repeated until formation of the structural layer 10 (FIG. 4).

FIGS. 4 and 5 illustrate the manufacturing of the following structural layer 10, formed above the previous structural layer 10. This following structural layer 10 comprises a second segment of the via 12 extending that of the previous structural layer 10, between two intercalary substrate portions 8. A manufacturing layer 14 is for example made by first adding the insulating material M1 (FIG. 4) and then the conductive material M2 (FIG. 5) or vice versa.

Alternatively, if this is possible depending on the three-dimensional (3D) geometry of the printed circuit 2, it is possible to add several layers for manufacturing a material before passing to the addition of several manufacturing layers of the other material.

The material addition operations are carried out manufacturing layer per manufacturing layer until the printed circuit of FIG. 1 is obtained.

The via 12 is then formed by an electrically conductive bulk block 16 extending through a hole 17 crossing the insulated substrate 4, the block 16 having a section mating that of the hole 17. Thus, the via 12 has low electric resistance as regards its diameter.

As illustrated in FIG. 1, a segment 18 of the via 12, here the upper segment is surrounded by a tubular substrate portion 19. This tubular substrate portion 19 gives the possibility of electrically insulating the via 12 from conductive elements 6 which are not electrically connected to this via 12. The tubular substrate portion 19 connects intercalary substrate portions 8 separated by conductive elements 6.

The substrate 4 comprises connecting substrate portions 21 connecting together intercalary substrate portions 8 separated by a conductive element 6. The tubular substrate portion 19 here includes a connecting substrate portion 21.

The manufacturing by additive manufacturing thus gives the possibility of manufacturing in the substrate connecting portions connecting substrate portions or substrate portions separated by a conductive element.

Additive manufacturing machines capable of using different materials which exist on the market, and for example are marketed by PHENIX SYSTEMS based in RIOM in France, under the names of PXL, PXM and PXS.

These machines are capable of using insulating ceramic or metals, which gives the possibility of manufacturing a printed circuit comprising an insulating ceramic substrate and metal conductive elements.

In an embodiment, such a machine is used by changing the material used by the machine every time that this is necessary during the manufacturing of the printed circuit by addition of material.

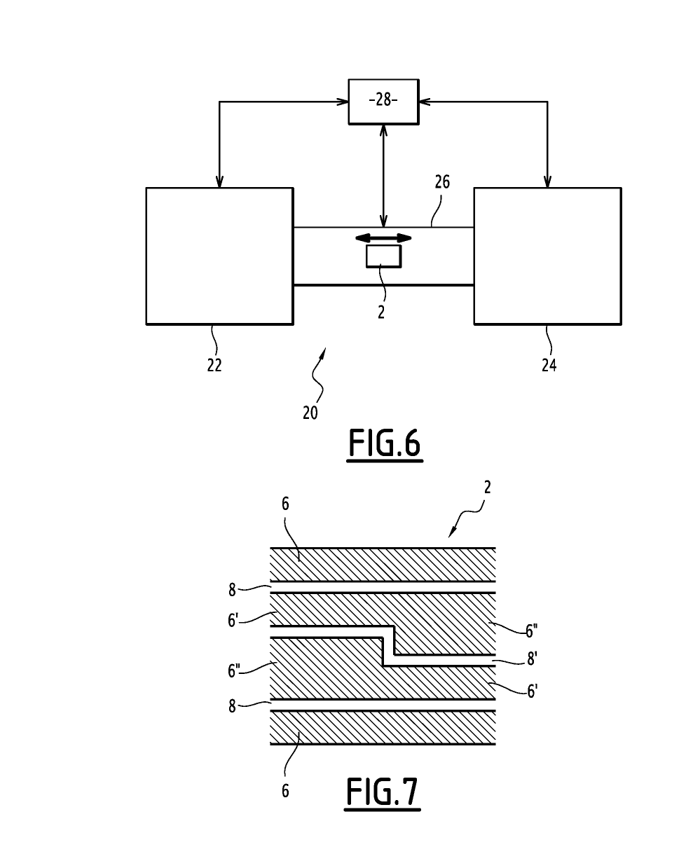

Alternatively, as illustrated in FIG. 6, it is possible to use an additive manufacturing system 20 comprising two distinct additive manufacturing machines 22, 24, each using a respective material, and transferring the printed circuit 2 from one machine to the other, at each change in added material during the additive manufacturing of the printed circuit 2, by means of a transfer device 26. A machine 22 uses the insulating material and the other machine 24 uses the conductive material. The transfer device 26 is synchronized with the machines 22, 24, gives the possibility of transferring the printed circuit 2 in synchronization with the operation of the machines 22, 24. The additive manufacturing system 20 comprises an electronic control unit 28 controlling the machines 22, 24 and the transfer device 26 in a synchronized way.

The printed circuit 2 of FIG. 1 has a relatively standard structure of a printed circuit, which is multilayer.

However, the additive manufacturing of the printed circuit, by manufacturing both the conductive elements and the substrate together by additive manufacturing, gives the possibility of obtaining particular shapes.

The printed circuit portion 2 illustrated in FIG. 7 comprises an alternating stack of conductive elements 6, 6′, 6″ and of intercalary substrate portions 8, 8′. It comprises a first thin conductive element 6′ and a second thick conductive element 6″ sandwiched between two substrate portions 8, 8′, located at a same level of the stack. The first conductive element 6′ has a first thickness strictly less than that of the second conductive element 6″. The first conductive element 6′ and the second conductive element 6″ are electrically connected. The first thin conductive element 6′ and the second thick conductive element 6″ may be used respectively for transmitting low energy signals and transmitting high energy signals.

At least one of the two substrate portions 8, 8′ sandwiching the first and second conductive elements 6′, 6″ has a displacement at the junction between the first thin conductive element 6′ and the second thick conductive element 6″ in order to take into account the thickness variation between the first and second conductive elements 6′, 6″. Here, one of the substrate portions 8 is planar and the other 8′ has a displacement.

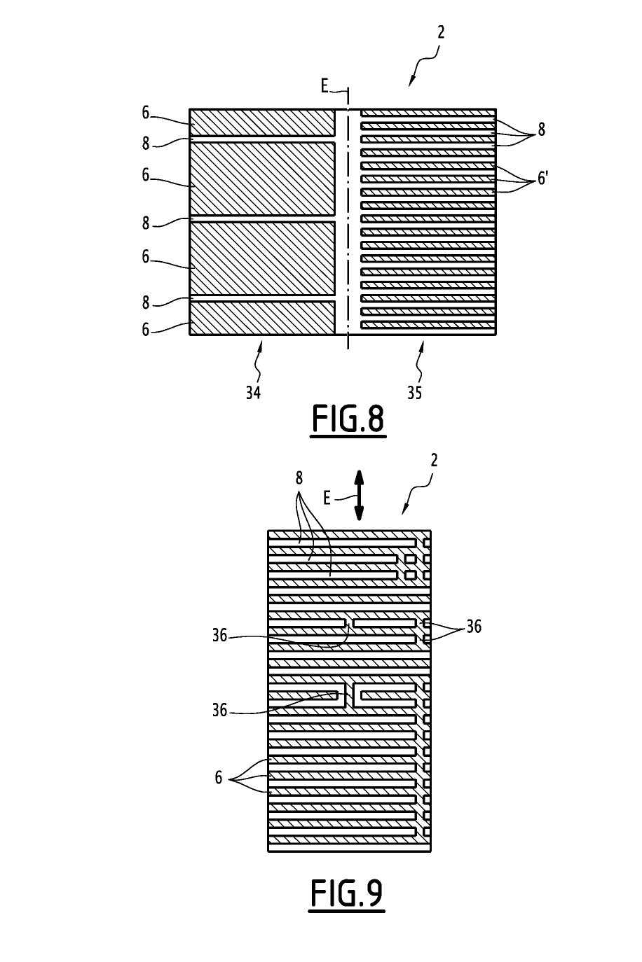

The printed circuit 2 of FIG. 8 has the shape of a plate, and comprises a first area 34 and a second area 35 each formed with an alternating stack of conductive elements 6, 6′ and of intercalary substrate portions 8 stacked along a stacking direction E.

The first area 34 has a number of conductive elements strictly less than that of the second area 35. The conductive elements 6′ of the first area 35 have a thickness strictly less than that of the conductive elements 6 of the second area 34. The first area 34 and the second area 35 here have the same thickness.

Indeed, with the additive manufacturing method, it is no longer necessary to provide thick conductive layers for transmitting high energy signals and thin conductive layers for transmitting low energy signals.

It becomes possible to have conductive elements for transmitting low energy signals and conductive elements for transmitting high energy signals located at a same level, sandwiched between two substrate portions like in FIG. 7 and/or to provide an area dedicated to high energy signals and another area dedicated to low energy signals like in FIG. 8.

The printed circuit 2 of FIG. 9 has the shape of a multilayer plate formed by a stack of alternating conductive elements 6 and intercalary substrate portions 8, and has buried vias 36 formed between conductive elements 6 separated by intercalary substrate portions 8 of the printed circuit organized as superposed layers. These buried vias 36 are much more easily manufactured, without any positioning constraint and may be combined with each other much more easily. With the traditional method, it would have been necessary to make a hole in the whole of the printed circuit and then metallize it so as to electrically connect the suitable layers. This method leads to the fact that the metallized hole is at the potential of the signal to be passed between different layers. The conductive layers in which the potential does not have to be brought have to be cut out around the via. The additive manufacturing gives the possibility of connecting two conductive layers without having to make a metallized hole through the whole of the printed circuit. By means of the invention, the conductive elements which are not placed between the conductive layers to be connected are spared, which gives the possibility of increasing their usable surface.

The printed circuit may also have a thermal drain function.

Thus, the printed circuit 70 of FIG. 11, according to the state of the art, gives the possibility of thermally connecting a cold plate 72 and a hot electronic component 74 in order to cool the latter. The printed circuit 70 comprises a thermal drain 76 formed with holes 78 (here four in number) crossing the printed circuit 70 and the internal surface 80 of which is metallized in order to provide a favorable heat path. Optionally, the holes 78 are filled with resin slightly promoting heat transfer.

Nevertheless, on the whole of the thermal drain 76, the amount of thermally conductive material is mostly a minority faced with the elements having poor heat conduction properties which are air or the resin used for filling the metallized hole and the material used as a substrate.

The thermal drain 76 should optionally ensure an electric insulation function since the electric potential of the electronic component 74 is not necessarily the same as the one of the cold plate 72. This electric insulation may be ensured by an electrically insulating element 82 placed between the printed circuit 70 and the cold plate 72. Now, the electrically insulating element 82 is generally also a heat insulator and the thickness of this electrically insulating element may be relatively large since it has to take into account the tolerances of the whole of the mechanical chain in order to ensure electric insulation under any circumstances. The addition of this electrically insulating element further degrades more the performances of the thermal draining 76.

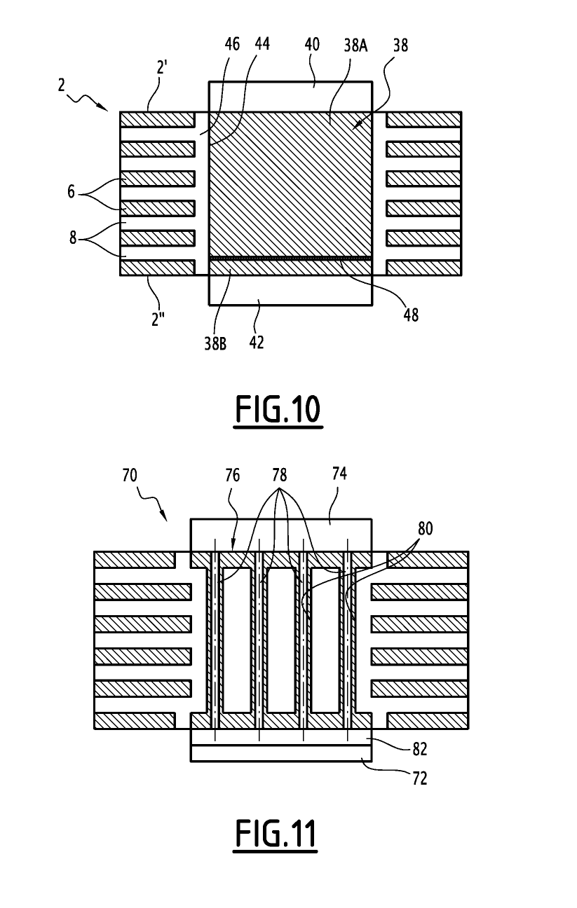

The printed circuit 2 of FIG. 10 comprises a thermal drain 38 crossing the printed circuit 2, between an electronic component 40 attached on a first face 2′ of the printed circuit 2 and a heat dissipating device 42 positioned on the second opposite face 2″ of the printed circuit 2.

The thermal drain 38 is made in a block of massive material manufactured by addition of the material. The thermal drain 38 is for example made in the same material as the conductive elements 6.

The thermal drain crosses an orifice 44 extending through the printed circuit 2 between the first face 2′ and the second face 2″. The orifice is tubular and delimited by a tubular substrate portion 46 formed in the substrate 4. The thermal drain 38 has a section mating that of the orifice 44, so that it fills the orifice 44.

Optionally, as illustrated in FIG. 10, the printed circuit 2 comprises an electric insulation layer 48 covering the area between the thermal drain and the heat dissipating device, or as in FIG. 10, between two portions 38A, 38B of the thermal drain 38. The electric insulation layer 48 electrically insulates the electronic component 40 from the heat dissipating device. The electric insulation layer 48 is formed by additive manufacturing together with the thermal drain 38 and the printed circuit as a whole.

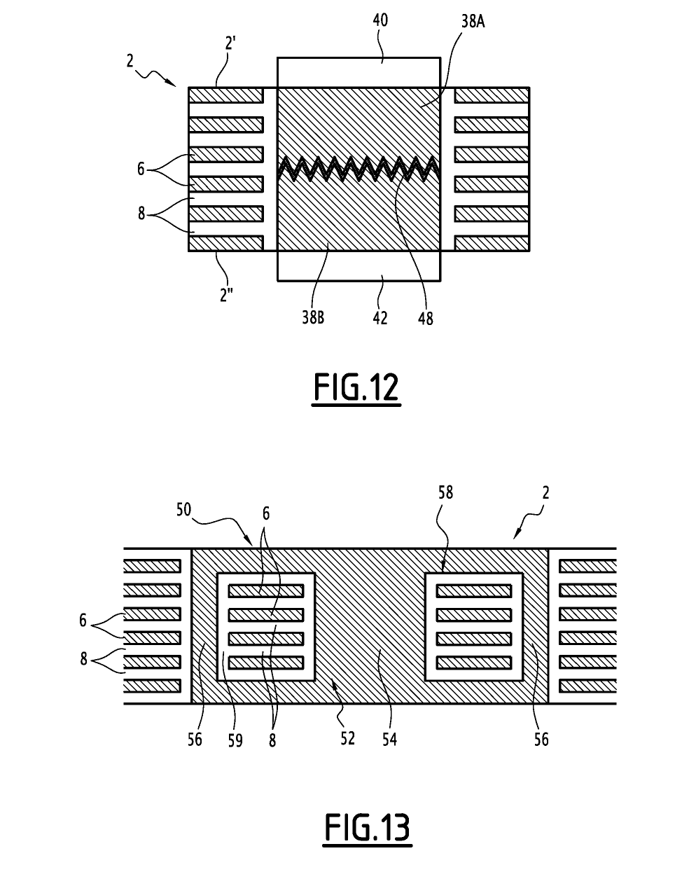

The printed circuit 2 of FIG. 12 here has an alternated stack of conductive elements 6 and of intercalary substrate portions 8. The thermal drain 38 crosses this stack right through, in the direction of the stacking direction.

The printed circuit of FIG. 12 differs from that of FIG. 10 in that the interface between both portions 38A, 38B of the thermal drain 38 separated by the electric insulation layer 48 is not planar but has nested mating raised/recessed portions. The result is that the electric insulation layer 48 has a three-dimensional shape with recesses and bumps, here as a section, a sawtooth shape. Other shapes are possible, for example a notched shape. Such a geometry gives the possibility of increasing the exchange surface area between both portions of the thermal drain 38, and of increasing the efficiency of the removal of heat in spite of the presence of the electric insulation layer 48.

The thermal drain 38, the electrical insulation layer 48, and optionally the thermal heat dissipating device 42, are each formed by additive manufacturing, during the additive manufacturing of the printed circuit 2.

In an embodiment, the electric insulation layer 48 is made in the same material as the substrate 4.

In another embodiment, the electric insulation layer 48 is made in a material different from that of the substrate 4. In this case, at least three materials are used for additive manufacturing of the printed circuit. To do this, an additive manufacturing machine is used suitable for using these materials or, similarly to FIG. 6, a system comprising at least three additive manufacturing machines each using a respective material, and an automatic transfer device for transferring the printed circuit from one machine to the other during the manufacturing.

FIG. 13 illustrates a printed circuit 2 comprising a magnetic component, here a magnetic circuit 50 provided in the thickness of the printed circuit 2. The magnetic circuit 50 comprises a magnetic core 52 comprising three parallel branches, including a central branch 54 and two side branches 56, the integrated circuit further comprising a coil 59 around the central branch.

The printed circuit 2 has a general shape of a multilayer plate and comprises, around the magnetic circuit 50, an alternating stack of intercalary substrate portions 8 and of conductive elements 6. The magnetic circuit 50 is formed in the volume of the printed circuit 2.

The printed circuit 2 including the magnetic circuit 50, is formed by manufacturing with addition of material. The coil 58 is formed with an alternating stack of substrate portions 8 and of conductive elements 6 formed during the additive manufacturing. The coil 58 is encapsulated into a shell 59 formed by the substrate 4 and separating the conductive elements 6 of the coil 58 from the magnetic circuit 50.

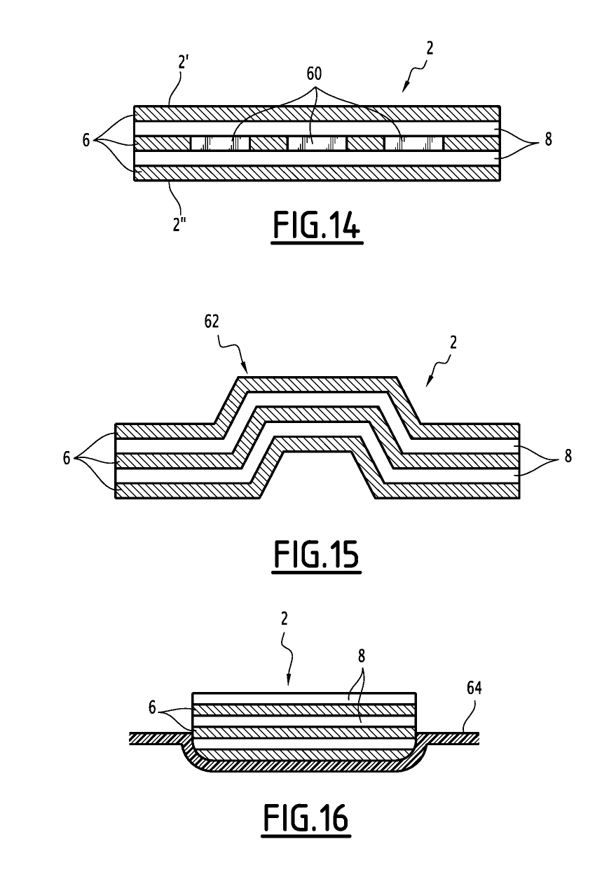

FIG. 14 illustrates a printed circuit 2 manufactured by addition of material, and comprising electronic components 60 embedder into the printed circuit 2. The electronic components 60 are embedded inside the printed circuit 2, at distances from the two opposite external faces 2′, 2″ of the printed circuit 2. They are here comprised in an internal layer sandwiched between two substrate portions 8, with conductive elements 6 also sandwiched between both of these substrate portions 8. The electronic components 60 are for example resistors and/or capacitors. They are obtained by additive manufacturing by adapting the material used or the arrangement of the different materials used. These embedded electronic components are protected and give the possibility of preserving the compactness of the printed circuit 2 by avoiding the making of metallized holes between the internal layer and one of the external faces, where the component is affixed.

The printed circuit 2 of FIG. 15 has a non-planar three-dimensional stable shape. The printed circuit 2 is self-supporting. It has here the shape of a plate with a boss 62. The printed circuit 2 is directly manufactured with this 3D shape by manufacturing with addition of material.

Thus, it is possible to give any shape to the printed circuit 2, depending on the available space in a casing of an electronic device into which the printed circuit should be integrated.

FIG. 16 illustrates an assembly comprising a printed circuit 2 and a shell 64 of a casing of an electronic device, the printed circuit 2 and the shell being manufactured together by additive manufacturing with. The printed circuit 2 is thus integrated to the shell 64 of the casing of the electronic device. This allows easy manufacturing, a compact arrangement and s robust assembly. The casing is for example a casing of a user telecommunication or geolocalization terminal, or an on board avionic computer. This joint manufacturing of the printed circuit and of the casing gives the possibility of thermally connecting them and dissipating heat energy, generated by the components affixed on the printed circuit, towards the casing.

The manufacturing of the substrate and of the conductive elements of a printed circuit by additive manufacturing gives the possibility of producing configurations which cannot be achieved with a manufacturing of a printed circuit by stacking elementary printed circuits comprising an insulating plate covered with one or two conductive layers.

It is also possible to produce the printed circuit with a multilayer structure comprising an alternating stack of conductive elements and of intercalary substrate portions, and allowing easier formation of embedded vias, without any manufacturing over cost and between any layers of the printed circuit.

It is also possible to produce the printed circuit with a multilayer structure by placing conductive elements of different thicknesses between two substrate portions, in order to give a three-dimensional shape to a substrate portion separating conductive elements, and/or further to provide connecting substrate portions connecting together intercalary substrate portions, for better insulation of the conductive elements.

It is further possible to form a massive thermal drain in an electrically conducting material, suitably removing the heat, which gives the possibility of reducing the section of the thermal drain as compared with a standard thermal drain. This gives the possibility of improving the cooling of the components and of improving the compactness of the printed circuit.

It is possible to integrate into the printed circuit, electronic components (resistance, capacitor . . . ) and/or magnetic components (magnetic circuit, magnetic coil . . . ), into the thickness of the printed circuit, or even into the internal layers of the printed circuit.

The printed circuit may be obtained with a particular three-dimensional shape and/or integrated into a shell of an electronic device.

All of this gives the possibility of having much more freedom in design. It remains possible to organize the printed circuit in alternating layers, but it also becomes possible to depart from this design mode, from the moment that there no longer exists any geometrical constraint.

The existent additive manufacturing machines give the possibility of manufacturing an integrated circuit with different insulating or conducting, magnetic or amagnetic materials.

1. The method for manufacturing a printed circuit comprising an electrically insulating substrate and electrically conductive elements borne by the substrate, the method comprising the step of: manufacturing the insulating substrate and the conductive elements together by additive manufacturing.

2. The manufacturing method according to claim 1, further comprising the step of: manufacturing at least one area in which a first conductive element and a second conductive element are sandwiched between two substrate portions, the first conductive element having a thickness, taken between two substrate portions, strictly smaller than a thickness of the second conductive element.

3. The manufacturing method according to claim 1, further comprising the step of: manufacturing a first distinct area and a second distinct area, each comprising an alternating stack of substrate portions and conductive elements, the first area and the second area having a number of conductive elements strictly less than the number of conductive elements of the second area.

4. The manufacturing method according to claim 1, further comprising the step of: manufacturing at least one area comprising at least one buried conductive via connecting two conductive elements separated by at least one substrate portion.

5. The manufacturing method according to claim 1, further comprising the step of: manufacturing at least one electronic component and at least one magnetic component formed in the thickness of the printed circuit.

6. The manufacturing method according to claim 1, further comprising the step of: manufacturing at least one thermal drain made in a hole crossing right through the printed circuit in the direction of the thickness, the thermal drain comprising at least one massive metal block with a section mating the thermal drain of the hole.

7. The manufacturing method according to claim 1, wherein the printed circuit is formed with a three-dimensional non-planar stable shape.

8. The manufacturing method according to claim 1, wherein the printed circuit is manufactured by adding material together with an electronic device shell.

9. A printed circuit obtained by the manufacturing method according to claim 1.

10. A printed circuit comprising an electrically insulating substrate and electrically conductive elements borne by the substrate, the printed circuit comprising at least one area in which a first conductive element and a second conductive element are sandwiched between two substrate portions, the first conductive element having a thickness, taken between both substrate portions, strictly smaller than a thickness of the second conductive element.

11. A printed circuit comprising an electrically insulating substrate and electrically conductive elements formed on the substrate, the printed circuit comprising a first distinct area and a second distinct area, each comprising an alternated stack of substrate portions and of conductive elements, the first area and the second area having a number of conductive elements strictly smaller than the number of conductive elements of the second area.

12. A printed circuit comprising an electrically insulating substrate and electrically conductive elements borne on the insulating substrate, the printed circuit comprising at least one electronic component and/or at least one magnetic component formed in the thickness of the printed circuit.

13. A printed circuit comprising an electrically insulating substrate and electrically conductive elements borne by the insulating substrate, the printed circuit comprising a thermal drain made in a hole crossing right through the printed circuit in the direction of the thickness, the thermal drain comprising at least one massive metal block with a section mating that a thickness of the hole.

14. A printed circuit comprising an electrically insulating substrate and electrically conductive elements borne by the insulating substrate, the printed circuit being formed with a non-planar stable three-dimensional shape.

15. A printed circuit comprising an electrically insulating substrate and electrically conductive elements borne by the insulating substrate, the printed circuit being manufactured by additive manufacturing together with an electronic device shell.
